(19) United States
(12) Patent Application Publication
(10) Pub. No.: US 2026/0212937 A1
(43) Pub. Date: Jul. 23, 2026

(54) MEMORY DEVICES, OPERATING METHODS THEREOF, AND MEMORY SYSTEMS

(71) Applicant: Yangtze Memory Technologies Co., Ltd., Wuhan (CN)

(72) Inventors: Wei Qi, Wuhan (CN); Lei Guan, Wuhan, Hubei (CN); Kaikai You, Wuhan, Hubei (CN); Wenping Chen, Wuhan, Hubei (CN); Da Li, Wuhan, Hubei (CN); Zikang Ai, Wuhan, Hubei (CN)

(21) Appl. No.: 19/282,850

(22) Filed: Jul. 28, 2025

(30) Foreign Application Priority Data
Jan. 23, 2025 (CN) 202510112366.6

(51) Int. Cl. G11C 16/32; G11C 16/08; G11C 16/10

(52) U.S. Cl. CPC G11C 16/32; G11C 16/08; G11C 16/102

(57) ABSTRACT

The examples of the present disclosure provide a memory device, an operating method thereof, and a memory system. The memory device includes: a memory cell array; word lines coupled to the memory cell array; a peripheral circuit coupled to the memory cell array and the word lines, wherein the peripheral circuit is configured to: in a first programming operation, apply a first pass voltage to a first group of word lines during a first time period; apply a second pass voltage greater than the first pass voltage to the first group of word lines during a second time period after the first time period; and apply a third pass voltage to a second group of word lines during a third time period.

### CROSS-REFERENCE TO RELATED APPLICATIONS

This application claims priority to and the benefit of Chinese Patent Application 202510112366.6, filed on Jan. 23, 2025, which is hereby incorporated by reference in its entirety.

### TECHNICAL FIELD

The present disclosure relates to the field of semiconductor technologies, and in particular to memory devices, methods, and memory systems.

### BACKGROUND

Memory devices have memory cells. A memory cell has a corresponding size. Over time, the sizes of memory cells in memory devices have become smaller.

### BRIEF DESCRIPTION OF DRAWINGS

FIG. 1 is a block diagram of a system having a memory device illustrated in an example of the present disclosure.

FIG. 2 is a schematic diagram of a memory card having a memory device illustrated in an example of the present disclosure.

FIG. 3 is a schematic diagram of a solid state drive having a memory device illustrated in an example of the present disclosure.

FIG. 4 is a schematic diagram of a memory device comprising a peripheral circuit illustrated in an example of the present disclosure.

FIG. 5 is a schematic cross-sectional view of a memory cell array comprising a memory string illustrated in an example of the present disclosure.

FIG. 6 is a block diagram of a memory device comprising a peripheral circuit illustrated in an example of the present disclosure.

FIG. 7 is a schematic diagram of performing programming operations on different word lines provided by some examples.

FIG. 8 is a timing diagram of performing programming operations on different word lines provided by some examples.

FIG. 9 is a schematic diagram of performing programming operations on different word lines provided by some examples of the present disclosure.

FIG. 10 is a timing diagram of performing programming operations on different word lines provided by some examples of the present disclosure.

FIG. 11 is a schematic diagram of performing programming operations on different word lines provided by some other examples of the present disclosure.

FIG. 12 is a timing diagram of performing programming operations on different word lines provided by some other examples of the present disclosure.

FIG. 13 is a timing diagram of performing programming operations on different word lines provided by still other examples of the present disclosure.

FIG. 14 is a schematic flowchart of an operating method of a memory device provided by an example of the present disclosure.

### DETAILED DESCRIPTION

The technical solutions in the examples of the present disclosure will be clearly and completely described below with reference to the examples of the present disclosure and the accompanying drawings, it is obvious that the described examples are just a part of the examples of the present disclosure, not all examples. Based on the examples of the present disclosure, all other examples obtained by those of ordinary skill in the art without creative efforts shall fall within the scope of the present disclosure.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described here, and well-known functions and structures are not described in detail.

In the accompanying drawings, size of a layer, a region, an element and their relative sizes may be exaggerated for clarity. Like reference numerals refer to like elements throughout.

It will be understood that when an element or layer is referred to as being “on,” “adjacent to,” “connected to” or “coupled to” another element or layer, it may be directly on, adjacent to, connected to or coupled to another element or layer, or there may be intervening elements or layers. In contrast, when an element is referred to as being “directly on,” “directly adjacent to,” “directly connected to” or “directly coupled to” another element or layer, there is no intervening elements or layers. It will be understood that, although the terms first, second, third etc., may be used to describe at least one of various elements, components, regions, layers or parts, at least one of these elements, components, regions, layers or parts should not be limited by these terms. These terms are just used to distinguish one element, component, region, layer or part from another element, component, region, layer or part. Thus, a first element, component, region, layer or part discussed below may be termed as a second element, component, region, layer or part without departing from teachings of the present disclosure. Whereas when a second element, component, region, layer or part is discussed, it does not indicate that a first element, component, region, layer or part necessarily presents in the present disclosure.

The spatially relative terms such as “beneath”, “below”, “lower”, “under”, “above”, “on”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the drawings. For example, if the device in the appended drawings is turned over, an element or a feature described as “below” or “beneath” or “under” another element or feature would then be oriented “above” the other element or feature. Thus, example terms “below” and “under” may encompass both orientations of up and down. A device may be otherwise oriented (rotated 90 degrees or at other orientations) and the spatially relative descriptors used herein is to be interpreted accordingly.

A term used herein is just for the purpose of describing a particular example and is not to be considered as limitation of the present disclosure. As used herein, “a”, “an” and “said/the” in a singular form are intended to include plural forms as well, unless the context indicated otherwise clearly. It should also be understood that at least one of the terms “consists of” or “comprising”, when used in this description, identify the presence of at least one of stated features, integers, steps, operations, elements or components, but do not exclude the presence or addition of at least one of one or more other features, integers, steps, operations, elements, components or groups. As used herein, the term “at least one of” includes any and all combinations of the related listed items.

For a thorough understanding of the present disclosure, detailed operations and detailed structures will be presented in the following description, in order to explain the technical solutions of the present disclosure. Some examples of the present disclosure are described in detail below, however, there may be other examples in the present disclosure in addition to these detailed descriptions.

For ease of understanding, the memory device in the examples of the present disclosure is described by taking a three-dimensional NAND type memory device as an example.

As the size of memory cells in memory devices becomes smaller and smaller, how to maintain the reliability of memory devices has become one of the challenges faced by those skilled in the art. Increasing the read margin may effectively improve the reliability of memory devices. Therefore, how to increase the read margin has become an urgent problem to be solved.

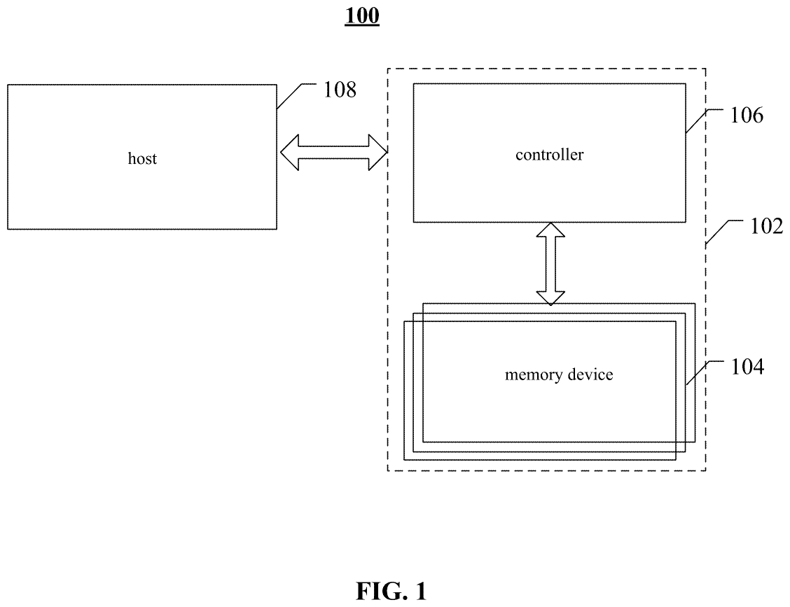

Referring to FIG. 1, FIG. 1 is a block diagram of a system having a memory device illustrated in an example of the present disclosure. As shown in FIG. 1, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

As shown in FIG. 1, the system 100 may comprise a host 108 and a memory system 102 having one or more memory devices 104 and a controller 106. The host 108 may be a processor (for example, a central processing unit (CPU)) or a system on chip (SoC) (for example, an application processor (AP)) of the electronic device. The host 108 may be configured to send data to the memory device 104 or receive data from the memory device 104.

In some examples, the controller 106 is coupled to the memory device 104 and the host 108, and is configured to control the memory device 104. The controller 106 may manage data stored in the memory device 104, and communicate with the host 108.

In some examples, the controller 106 is designed to operate in a low duty cycle environment, such as a secure digital (SD) card, a compact flash (CF) card, a universal serial bus (USB) flash drive, or other media for use in electronic devices such as personal computers, digital cameras, mobile phones, and the like.

In some examples, the controller 106 is designed to operate in a high duty cycle environment solid state drive (SSD) or embedded multi-media card (eMMC), which serves as a data storage for mobile devices such as smart phones, tablet computers, laptop computers, and the like, as well as enterprise storage arrays.

The controller 106 may be configured to control operations of the memory device 104, for example, read, erase, and programming operations. The controller 106 may also be configured to manage various functions regarding data stored in or to be stored in the memory device 104, comprising, but not limited to, bad block management, garbage collection, translation of a logical address to a physical address, wear leveling, and the like. In some examples, the controller 106 is further configured to process error correcting code (ECC) regarding data read from the memory device 104 or written to the memory device 104.

The controller 106 may also perform any other suitable functions, for example, formatting the memory device 104. The controller 106 may communicate with an external device (e.g., host 108) according to a particular communication protocol. For example, the controller 106 may communicate with the external device through at least one of various interface protocols, for example, a USB protocol, an MMC protocol, a peripheral component interconnect (PCI) protocol, a PCI Express (PCI-E) protocol, an advanced technology attachment (ATA) protocol, a serial ATA protocol, a parallel ATA protocol, a small computer system interface (SCSI) protocol, an enhanced small drive interface (ESDI) protocol, an integrated drive electronics (IDE) protocol, a Firewire protocol, and the like.

The controller 106 and one or more memory devices 104 may be integrated into various types of storage devices, e.g., comprised in the same package (e.g., universal flash storage (UFS) package or eMMC package). That is, the memory system 102 may be implemented and packaged into different types of terminal electronics.

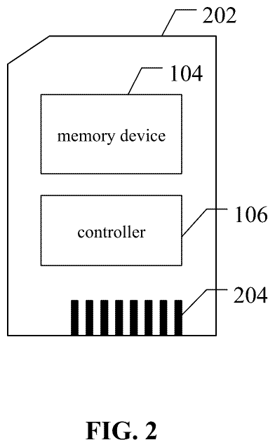

Referring to FIG. 2, FIG. 2 is a schematic diagram of a memory card having a memory device illustrated in an example of the present disclosure. As shown in FIG. 2, the controller 106 and a single memory device 104 may be integrated into a memory card 202. The memory card 202 may comprise a personal computer memory card international association (PCMCIA) card, a CF card, a smart media (SM) card, a memory stick, a multimedia card (for example, an MMC, a reduced-size MMC (RS-MMC), a micro MMC (microMMC)), an SD (for example, an SD, a mini SD (miniSD), a micro SD (microSD), a secure digital high capacity (SDHC)) card, a UFS, and the like. The memory card 202 may also comprise a memory card connector 204 that couples the memory card 202 with a host (e.g., the host 108 in FIG. 1).

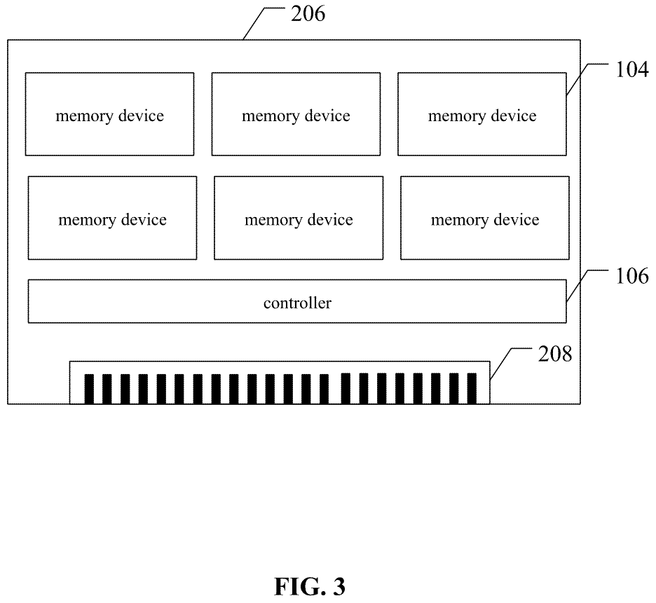

Referring to FIG. 3, FIG. 3 is a schematic diagram of a solid state drive having memory devices illustrated in an example of the present disclosure. As shown in FIG. 3, a controller 106 and a plurality of memory devices 104 may be integrated into a solid state drive 206. The solid state drive 206 may also comprise a solid state drive connector 208 that couples the solid state drive 206 with a host (e.g., the host 108 in FIG. 1). In some examples, at least one of storage capacity or operating speed of the solid state drive 206 is greater than at least one of storage capacity or operating speed of the memory card 202.

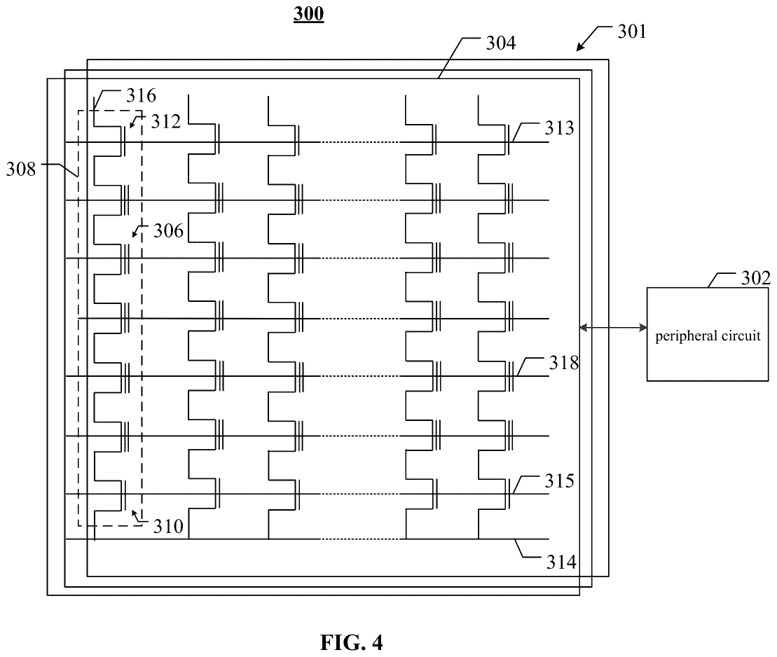

Referring to FIG. 4, FIG. 4 is a schematic diagram of a memory device comprising a peripheral circuit illustrated in an example of the present disclosure. A memory device 300 may be an example of the memory device 104 in FIG. 1. The memory device 300 may comprise a memory cell array 301 and a peripheral circuit 302 coupled to the memory cell array 301. The memory cell array 301 may be an array of NAND flash memory cells, where memory cells 306 are provided in the form of an array of memory strings 308 each extending vertically above a substrate (not shown in FIG. 4). In some examples, each memory string 308 comprises a plurality of memory cells 306 coupled in series and stacked vertically. Each memory cell 306 may sustain continuous analog values, e.g., voltage or charge, depending on the number of electrons captured within the area of the memory cell 306. Each memory cell 306 may be a floating gate type memory cell comprising a floating gate transistor, or a charge trapping type memory cell comprising a charge trapping transistor.

In some examples, each memory cell 306 may be a Single-Level Cell (SLC) having two possible storage states and thus may store one bit of data. For example, the SLC may have a first storage state “1” and a second storage state “0”, where a threshold voltage distribution of the first storage state “1” may correspond to a first voltage range, and a threshold voltage distribution of the second storage state “0” may correspond to a second voltage range. The first storage state is an erased state, and the second storage state is a programmed state. In some examples, each memory cell 306 is a multi-level cell (MLC) capable of storing more than a single bit of data in more than four storage states. For example, an MLC may store two bits of data per cell, three bits of data per cell (also known as triple-level Cell (TLC)), or four bits of data per cell (also known as quad-level cell (QLC)). Each MLC may be programmed to take a voltage range of possible threshold voltage distributions. In one example, if each MLC stores two bits of data, the MLC may have a first storage state “11”, a second storage state “10”, a third storage state “01”, and a fourth storage state “00”, where the threshold voltage distributions of the first, second, third, and fourth storage states correspond to the first, second, third, and fourth voltage ranges, respectively. The first storage state is an erased state, and the second, third and fourth storage states are each programmed state. Similarly, the TLC may have 8 storage states comprising the erased state and 7 programmed states; and the QLC may have 16 storage states comprising the erased state and 15 programmed states.

As shown in FIG. 4, each memory string 308 may comprise a source selective transistor 310 (SST) at its source terminal and a drain selective transistor 312 (DST) at its drain terminal. The source selective transistor 310 and the drain selective transistor 312 may be configured to activate a selected memory string 308 (a column of the array) during read and programming operations. In some examples, the sources of the memory strings 308 in the same memory block 304 are coupled through the same source line 314 (e.g., common SL). In other words, in some examples, all the memory strings 308 in the same memory block 304 have an array common source (ACS). In some examples, the drain of the drain selective transistor 312 of each memory string 308 is coupled to a respective bit line (BL) 316 from which data may be read or written via an output bus (not shown in FIG. 4). In some examples, each memory string 308 is configured to be selected or deselected by at least one of: applying a select voltage (e.g., higher than a threshold voltage of the drain selective transistor 312) or a deselect voltage (e.g., 0V) to a respective drain selective transistor 312 via one or more drain selective lines (DSL) 313, or applying a select voltage (e.g., higher than a threshold voltage of the source selective transistor 310) or a deselect voltage (e.g., 0V) to a respective source selective transistor 310 via one or more source selective lines (SSL) 315.

As shown in FIG. 4, the memory strings 308 may be organized into a plurality of memory blocks 304, each of which may have a source line 314 (e.g., a common SL coupled to ground). In some examples, each memory block 304 is a basic data unit for performing an erase operation, e.g., all memory cells 306 on the same memory block 304 are erased simultaneously. To erase the memory cell 306 in the selected memory block, the source line 314 coupled to the selected memory block and the unselected memory block in the same plane as the selected memory block may be biased with an erase voltage Vers (e.g., a high positive voltage (e.g., 20V or higher)). It should be understood that in some examples, erase operation may be performed at a half-memory block level, at a quarter-memory block level, or at a level with any suitable number of memory blocks or any suitable fraction of a memory block. A memory cells 306 of adjacent memory strings 308 may be coupled by word lines (WL) 318 that select which row of memory cells 306 is affected by read and programming operations.

It should be noted that, for the SLC, each memory cell may store 1 bit of information, such that information stored in a layer of memory cell (that is, 1 physical page) at the physical level corresponds to information of 1 logical page. For the MLC, each memory cell may store 2 bits of information, such that information stored in a layer of memory cell (that is, 1 physical page) at the physical level corresponds to information of 2 logical pages. For the TLC, each memory cell may store 3 bits of information, such that information stored in a layer of memory cell (that is, 1 physical page) at the physical level corresponds to information of 3 logical pages. For the QLC, each memory cell may store 4 bits of information, such that information stored in a layer of memory cell (that is, 1 physical page) at the physical level corresponds to information of 4 logical pages.

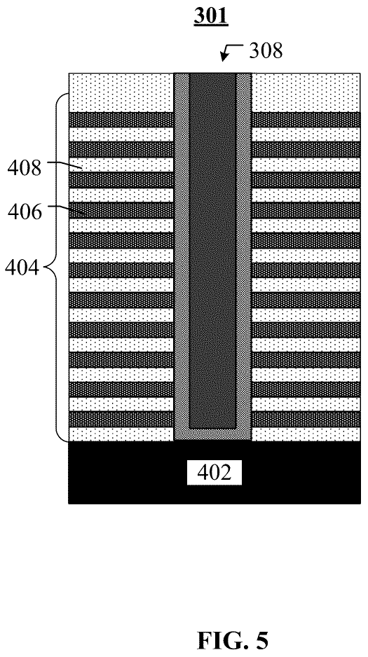

Referring to FIG. 5, FIG. 5 is a schematic cross-sectional view of a memory cell array comprising a memory string illustrated in an example of the present disclosure. As shown in FIG. 5, the memory string 308 may extend vertically through the memory stack layer 404 over the substrate 402. The substrate 402 may comprise silicon (e.g., monocrystalline silicon), silicon germanium (SiGe), gallium arsenide (GaAs), germanium (Ge), silicon-on-insulator (SOI), Ge-on-insulator (GOI), or any other suitable material.

The memory stack layer 404 may comprise alternating gate conductive layers 406 and gate dielectric layers 408. The number of pairs of gate conductive layers 406 and gate dielectric layers 408 in the memory stack layer 404 may determine the number of memory cells 306 in the memory cell array 301. The gate conductive layer 406 may comprise a conductive material, comprising, but not limited to, tungsten (W), cobalt (Co), copper (Cu), aluminum (Al), polysilicon, doped silicon, silicide, or any combination thereof. In some examples, each gate conductive layer 406 comprises a metal layer, for example, a tungsten layer. In some examples, each gate conductive layer 406 comprises a doped polysilicon layer. Each gate conductive layer 406 may comprise a control gate surrounding the memory cell 306 and may extend laterally at the top of the memory stack layer 404 as the drain selective line 313, laterally at the bottom of the memory stack layer 404 as the source selective line 315, or laterally between the drain selective line 313 and the source selective line 315 as the word line 318.

As shown in FIG. 5, the memory string 308 comprises a channel structure that extends vertically through the memory stack layer 404. In some examples, the channel structure comprises a channel hole filled with (one or more) semiconductor material(s) (e.g., as a semiconductor channel) and (one or more) dielectric material(s) (e.g., as a memory film). In some examples, the semiconductor channel comprises silicon, e.g., polysilicon. In some examples, the memory film is a composite dielectric layer comprising a tunneling layer, a storage layer (also referred to as a “charge trapping/storage layer”), and a blocking layer. The channel structure may have a cylindrical shape (e.g., a pillar shape). According to some examples, the semiconductor channel, the tunneling layer, the storage layer, and the blocking layer are arranged radially from the center of the pillar toward the outer surface of the pillar in this order. The tunneling layer may comprise silicon oxide, silicon oxynitride, or any combination thereof. The storage layer may comprise silicon nitride, silicon oxynitride, or any combination thereof. The blocking layer may comprise silicon oxide, silicon oxynitride, a high dielectric constant (high-k) dielectric, or any combination thereof. In one example, the memory film may comprise a composite layer of silicon oxide/silicon oxynitride/silicon oxide (ONO).

According to some examples, a well (e.g., at least one of a P-well or N-well) may be formed in the substrate 402, and a source terminal of the memory string 308 is in contact with the well. For example, a source line may be coupled to the well to apply an erase voltage to the well (e.g., the source of the memory string) during an erase operation. In some examples, the memory string further comprises a channel plug at the drain terminal of the memory string 308. It should be understood that although not illustrated in FIG. 5, additional components of the memory cell array 301 may be formed, comprising, but not limited to, gate line slot/source contacts, local contacts, interconnect layers, and the like.

Referring back to FIG. 4, the peripheral circuit 302 may be coupled to the memory cell array 301 through bit lines 316, word lines 318, a source line 314, a source selective line 315, and a drain selective line 313. The peripheral circuit 302 may comprise any suitable analog, digital, and mixed-signal circuit for facilitating operation of the memory cell array 301 by applying at least one of voltage signals or current signals to each target memory cell 306 and sensing at least one of voltage signals or current signals from each target memory cell 306 via bit lines 316, word lines 318, a source line 314, a source selective line 315, and a drain selective line 313. The peripheral circuit 302 may comprise various types of peripheral circuits formed using metal oxide semiconductor (MOS) technology.

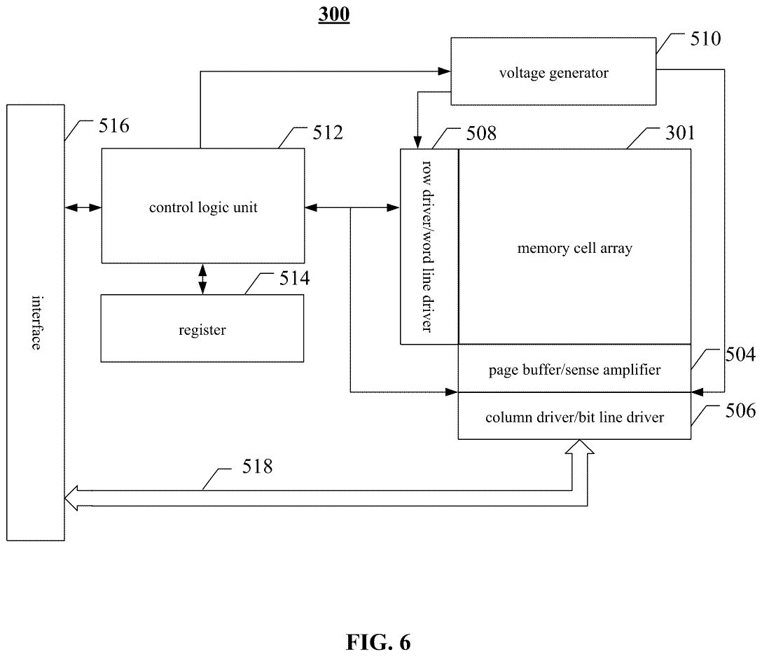

Referring to FIG. 6, FIG. 6 is a block diagram of a memory device comprising a peripheral circuit illustrated in an example of the present disclosure. As shown in FIG. 6, the peripheral circuit comprises a page buffer/sense amplifier 504, a column driver/bit line driver 506, a row driver/word line driver 508, a voltage generator 510, a control logic unit 512, a register 514, an interface (I/F) 516, and a data bus 518. It should be understood that in some examples, additional peripheral circuits not shown in FIG. 6 may also be comprised.

The page buffer/sense amplifier 504 may be configured to read data from the memory cell array 301 and program (write) data into the memory cell array 301 according to control signals from the control logic unit 512. In another example, the page buffer/sense amplifier 504 may perform a programming verify operation to ensure that the data has been properly programmed into the memory cell 306 coupled to the selected word line 318. In yet another example, the page buffer/sense amplifier 504 may also sense a low power signal from the bit line 316 representing a data bit stored in the memory cell 306, and amplify a small voltage swing to an identifiable logic level in a read operation. Column driver/bit line driver 506 may be configured to be controlled by control logic unit 512 and select one or more memory string 308 by applying a bit line voltage generated from voltage generator 510.

The row driver/word line driver 508 may be configured to be controlled by the control logic unit 512 and select/deselect the memory block 304 of the memory cell array 301 and select/deselect the word line 318 of the memory block 304. The row driver/word line driver 508 may also be configured to drive the word line 318 using the word line voltage generated from the voltage generator 510. In some examples, row driver/word line driver 508 may also select/deselect and drive source selective line 315 and drain selective line 313. As described in detail below, the row driver/word line driver 508 is configured to perform an erase operation on the memory cells 306 coupled to the (one or more) selected word line(s) 318. The voltage generator 510 may be configured to be controlled by the control logic unit 512 and generate word line voltages (e.g., reading voltages, programming voltages, pass voltages, local voltages, verifying voltages, etc.), bit line voltages, and source line voltages to be supplied to the memory cell array 301.

Control logic unit 512 may be coupled to each peripheral circuit described above and configured to control the operations of each peripheral circuit. Register 514 may be coupled to control logic unit 512 and comprises status register, command register, and address register for storing status information, command operation codes (OP codes), and command addresses for controlling the operations of each peripheral circuit. The interface 516 may be coupled to the control logic unit 512 and act as a control buffer to buffer control commands received from the host (not shown in FIG. 6) and relay them to the control logic unit 512, and buffer status information received from the control logic unit 512 and relay it to the host. The interface 516 may also be coupled to the column driver/bit line driver 506 via a data bus 518 and act as a data input/output (I/O) interface and a data buffer to buffer data and relay it to the memory cell array 301, or relay or buffer data from the memory cell array 301.

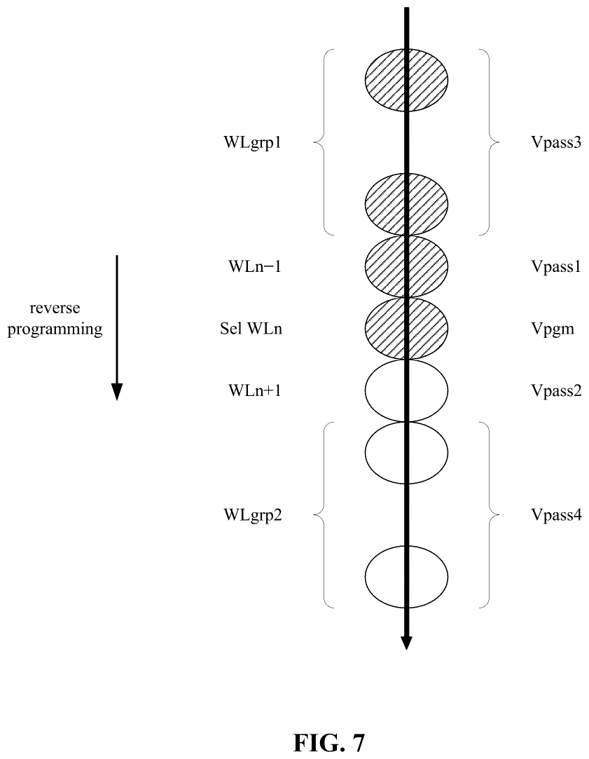

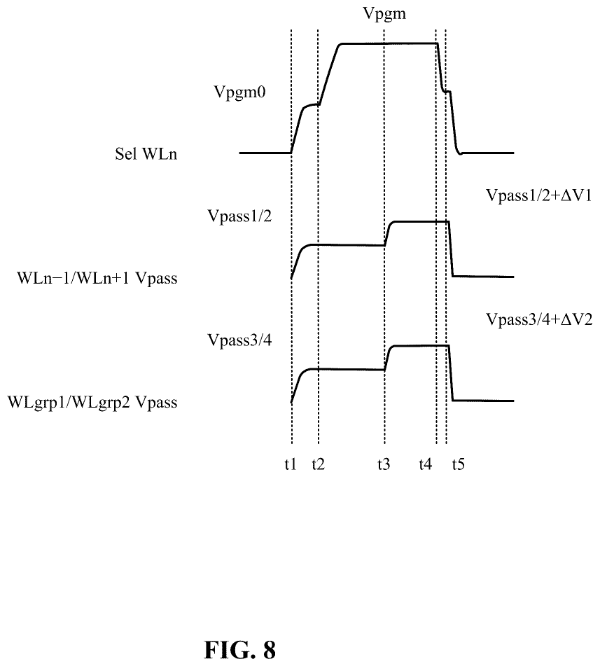

Referring to FIG. 7 and FIG. 8, FIG. 7 is a schematic diagram of performing programming operations on different word lines provided by some examples, and FIG. 8 is a timing diagram of performing programming operations on different word lines provided by some examples. As shown in FIG. 7, a plurality of word lines are arranged between bit lines and a source line, and the plurality of word lines comprise a selected word line Sel WLn and unselected word lines. The unselected word lines may be divided into two categories according to different relative positional relationships between the unselected word lines and the selected word line. The first category of unselected word lines comprise the unselected word lines WLn+1 and WLn−1 adjacent to the selected word line, and the second category of unselected word lines comprise a plurality of unselected word lines WLgrp1 arranged between the bit lines and the unselected word line WLn−1, and a plurality of unselected word lines WLgrp2 arranged between the source line and the unselected word line WLn+1.

It should be noted that in FIG. 7, the example where the programming order is in reverse programming is just taken as an example, and in this case, the memory cells coupled to the unselected word lines WLn−1 and WLgrp1 are in a programmed state, and the memory cells coupled to the unselected word lines WLn+1 and WLgrp2 are in an unprogrammed state.

As shown in FIG. 8, in a process of performing programming operations, at a first time t1, an initial programming voltage Vpgm0 is applied to the selected word line Sel WLn, a first pass voltage Vpass1 is applied to the unselected word line WLn−1, a second pass voltage Vpass2 is applied to the unselected word line WLn+1, a third pass voltage Vpass3 is applied to the unselected word line WLgrp1, and a fourth pass voltage Vpass 4 is applied to the unselected word line WLgrp2; where the initial programming voltage Vpgm0 is less than the programming voltage Vpgm.

At a second time t2, a programming voltage Vpgm is applied to the selected word line Sel WLn. Here, considering that the programming voltage Vpgm is larger, the selected word line Sel WLn may be boosted twice to reach the programming voltage Vpgm, where the selected word line Sel WLn is boosted to the initial programming voltage Vpgm0 at the first time t1, and the selected word line Sel WLn is boosted to the programming voltage Vpgm greater than the initial programming voltage Vpgm0 at the second time t2.

At a third time t3, a fifth pass voltage (e.g., Vpass1+ΔV1) is applied to the unselected word line WLn−1, a sixth pass voltage (e.g., Vpass2+ΔV1) is applied to the unselected word line WLn+1, a seventh pass voltage (e.g., Vpass3+ΔV2) is applied to the unselected word line WLgrp1, and an eighth pass voltage (e.g., Vpass4+ΔV2) is applied to the unselected word line WLgrp2. Here, the unselected word line WLn−1 is taken as an example for description, the unselected word line WLn−1 is boosted twice to reach the fifth pass voltage, where the unselected word line WLn−1 is boosted to the first pass voltage Vpass1 at the first time t1, and the unselected word line WLn−1 is boosted to a fifth pass voltage greater than the first pass voltage Vpass1 at the third time t3. Similarly, the unselected word lines WLn+1, WLgrp1 and WLgrp2 may each be boosted twice to reach the target pass voltage.

At the fourth time t4, the selected word line Sel WLn starts to be discharged.

At the fifth time t5, the unselected word lines WLn−1, WLn+1, WLgrp1 and WLgrp2 all start to be discharged.

In the above technical solution, the unselected word lines are all boosted twice to reach the target pass voltage, and the timings of boosting the unselected word lines twice are the same, that is, the first boosting is performed at the first time t1 as the start time and the second boosting is performed at the third time t3 as the start time. In this case, during the second boosting on the unselected word lines, the voltages of the selected word line may be coupled up once to increase the effective voltages of the selected word line.

In combination with the above technical solutions, an MLC is taken as an example to explain the meaning of “read margin” herein. The MLC may have a first storage state “11”, a second storage state “10”, a third storage state “01”, and a fourth storage state “00”, and the threshold voltage distributions of the first, second, third, and fourth storage states correspond to the first, second, third, and fourth voltage ranges, respectively. A read margin refers to a distance between the voltage ranges corresponding to different storage states. The larger the read margin, the larger the distance between different voltage ranges, the higher the reliability of the memory device. In the above technical solution, the read margin still needs to be further increased.

In view of this, examples of the present disclosure provide a memory device, an operating method thereof, and a memory system.

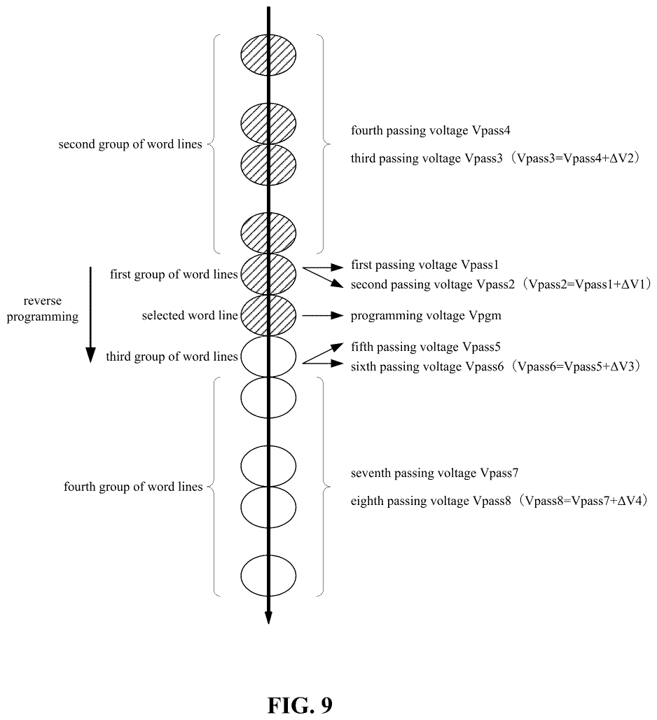

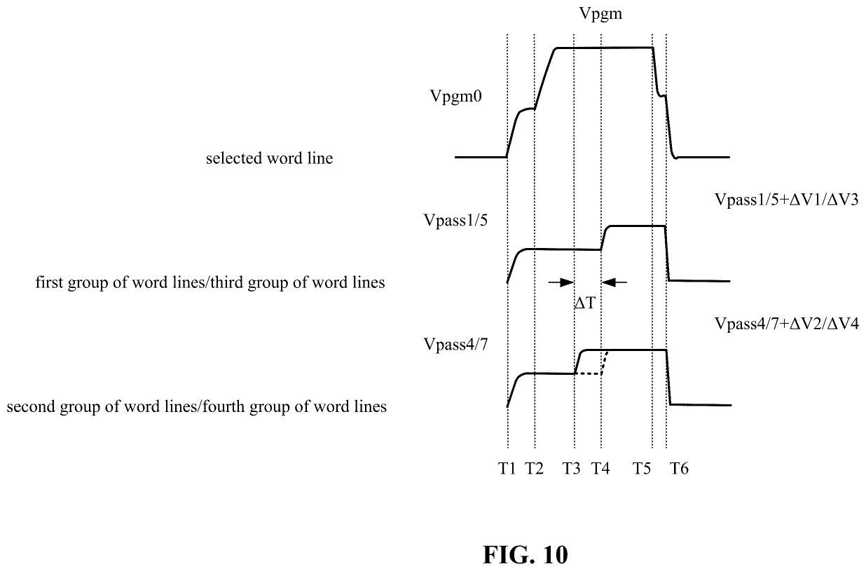

Referring to FIG. 9 and FIG. 10, FIG. 9 is a schematic diagram of performing programming operations on different word lines provided by some examples of the present disclosure, and FIG. 10 is a timing diagram of performing programming operations on different word lines provided by some examples of the present disclosure. As shown in FIG. 4, FIG. 9, and FIG. 10, an example of the present disclosure provides a memory device, and the memory device 300 comprises: a memory cell array 301; a plurality of word lines 318 coupled to the memory cell array 301, where the plurality of word lines comprises a selected word line and unselected word lines, and the unselected word lines comprises at least a first group of word lines and a second group of word lines; a peripheral circuit 302 coupled to the memory cell array 301 and the word lines 318, where the peripheral circuit 302 is configured to: in a first programming operation, apply a first pass voltage Vpass1 to the first group of word lines for a first time period; apply a second pass voltage Vpass2 greater than the first pass voltage Vpass1 to the first group of word lines for a second time period after the first time period; and apply a third pass voltage Vpass3 to the second group of word lines for a third time period; where a start time of the second time period is different from a start time of the third time period, and the start time of the third time period is later than a start time of the first time period.

In some examples, the memory device 300 further comprises: a plurality of bit lines 316 coupled to the memory cell array 301; a source line 314 coupled to the memory cell array 301; where both the selected word line and the unselected word lines are arranged between the bit lines 316 and the source line 314, and the unselected word lines comprise at least a first group of word lines and a second group of word lines. Here, the first group of word lines comprise at least 1 unselected word lines, and the second group of word lines comprise at least 1 unselected word lines. The number of word lines comprised in the first group of word lines and the second group of word lines may be appropriately selected in consideration of the total number of word lines comprised in the memory device.

Here, there may be different relative positional relationships between the selected word line, the first group of word lines and the second group of word lines, which will be explained hereinafter.

In some examples, the selected word line may be arranged between the first group of word lines and the second group of word lines; where the first group of word lines may be arranged between the bit lines and the selected word line, and the second group of word lines may be arranged between the source line and the selected word line; or, the first group of word lines may be arranged between the source line and the selected word line, and the second group of word lines may be arranged between the bit lines and the selected word line.

In some other examples, the first group of word lines are arranged between the selected word line and the second group of word lines; where both the first group of word lines and the second group of word lines are arranged between the bit lines and the selected word line; or both the first group of word lines and the second group of word lines are arranged between the source line and the selected word line.

In some examples, the unselected word lines may further comprise: a third group of word lines and a fourth group of word lines, where the third group of word lines are arranged between the selected word line and the fourth group of word lines. Here, the third group of word lines comprise at least 1 unselected word lines, and the fourth group of word lines comprise at least 1 unselected word lines. The number of word lines comprised in the third group of word lines and the fourth group of word lines may be appropriately selected in consideration of the total number of word lines comprised in the memory device.

In some examples, both the first group of word lines and the second group of word lines are arranged between the selected word line and the bit lines, and both the third group of word lines and the fourth group of word lines are arranged between the selected word line and the source line. In some other examples, both the first group of word lines and the second group of word lines are arranged between the selected word line and the source line, and both the third group of word lines and the fourth group of word lines are arranged between the selected word line and the bit lines.

For ease of description, in combination with FIG. 9, the relative positional relationships between the first group of word lines, the second group of word lines, the third group of word lines, and the fourth group of word lines are defined. Both the first group of word lines and the second group of word lines are arranged between the bit lines and the selected word line, and the first group of word lines are arranged between the selected word line and the second group of word lines; both the third word line and the fourth group of word lines are arranged between the source line and the selected word line, and the third group of word lines are arranged between the selected word line and the fourth group of word lines.

In some examples, the number of word lines comprised in the first group of word lines ranges from 1 through 5, and the number of word lines comprised in the third group of word lines ranges from 1 through 5. Here, the distance between the first group of word lines and the selected word line is smaller than the distance between the second group of word lines and the selected word line; and the distance between the third group of word lines and the selected word line is smaller than the distance between the fourth group of word lines and the selected word line. Therefore, the voltage variation of the word lines comprised in the first group of word lines and the third group of word lines with a smaller distance from the selected word line has a greater impact on the selected word line. FIG. 9 just takes the first group of word lines and the third group of word lines both comprising 1 word line as an example for illustration, which does not constitute a limitation on the scope of the present disclosure.

In some examples, when the first programming operation is in forward programming, the memory cells coupled to a group of word lines arranged between the selected word line and the source line are in a programmed state, and the memory cells coupled to a group of word lines arranged between the selected word line and the bit lines are in an unprogrammed state; or when the first programming operation is in reverse programming, the memory cells coupled to a group of word lines arranged between the selected word line and the source line are in an unprogrammed state, and the memory cells coupled to a group of word lines arranged between the selected word line and the bit lines are in a programmed state. FIG. 9 just takes the first programming operation being a reverse programming as an example for illustration, which does not constitute a limitation on the scope of the present disclosure.

The meanings of the “voltage establishing duration”, the “near end of the selected word line” and the “far end of the selected word line” are explained hereinafter with reference to this example. The voltage establishing duration refers to a duration between a time when the target voltage is applied to the word line and a time when the word line reaches the target voltage. For example, at a certain time, the programming voltage Vpgm is applied to the selected word line, which does not mean that at that time the voltage of the selected word line may reach the programming voltage Vpgm. In other words, at a certain time, the programming voltage Vpgm is applied to the selected word line, which indicates that the voltage of the selected word line starts to ramp up at this time as the start time, and after the voltage establishing duration is elapsed, the voltage of the selected word line reaches the programming voltage Vpgm. Similarly, the target pass voltage is applied to the unselected word line, and the voltage of the unselected word line may also reach the target pass voltage only after the voltage establishing duration is elapsed. For different word lines, the voltage establishing durations may be the same or different.

The distance between the near end of the selected word line and the position where the selected word line receives external operating voltage is less than the distance between the far end of the selected word line and the position where the selected word line receives external operating voltage. For example, at a certain time, the programming voltage Vpgm is applied to the selected word line, and due to the existence of the word line resistor, the response speed of the near end of the selected word line to the external operating voltage is faster than the response speed of the far end of the selected word line to the external operating voltage, that is, the duration required for the near end of the selected word line to boost to reach the programming voltage Vpgm at this time as the start time is less than the duration required for the far end of the selected word line to boost to the programming voltage Vpgm at this time as the start time. In this way, in the process of boosting the selected word line to the programming voltage Vpgm, the voltage difference between the near end of the selected word line and the far end of the selected word line (Sel WL near far gap) may be measured at the same time.

In the example of the present disclosure, a first pass voltage Vpass1 is applied to the first group of word lines for a first time period; and a second pass voltage Vpass2 greater than the first pass voltage Vpass1 is applied to the first group of word lines for a second time period after the first time period. That is, during a process of the first programming operation, the first group of word lines may be boosted twice to reach the second pass voltage Vpass2, where the first group of word lines are first boosted to the first pass voltage Vpass1 for the first time period, and the first group of word lines are then boosted to the second pass voltage Vpass2 for the second time period. A third pass voltage Vpass3 is applied to the second group of word lines for a third time period; where the start time of the second time period is different from the start time of the third time period, and the start time of the third time period is later than the start time of the first time period. That is, the start time when the second group of word lines are boosted to the third pass voltage Vpass3 is later than the start time when the first group of word lines are boosted to the first pass voltage Vpass1, and the start time when the second group of word lines are boosted to the third pass voltage Vpass3 is different from the start time when the first group of word lines are boosted to the second pass voltage Vpass2. In this way, in the process of boosting the second group of word lines to the third pass voltage Vpass3 and boosting the first group of word lines to the second pass voltage Vpass2, the voltage of the selected word line may be coupled up twice to increase the effective voltage of the selected word line, improve the voltage difference between the near end of the selected word line and the far end of the selected word line, such that the local boosting is increased and the read margin is increased, and in turn the reliability of the memory device is improved.

The following will be described in detail in combination with FIG. 10. As shown in FIG. 10, in the process of performing the first programming operation, at a first time T1, an initial programming voltage Vpgm0 is applied to the selected word line, a first pass voltage Vpass1 is applied to the first group of word lines, and a fourth pass voltage Vpass4 is applied to the second group of word lines.

In some examples, the first pass voltage Vpass1 and the fourth pass voltage Vpass4 may be the same or different. The specific values of the first pass voltage Vpass1 and the fourth pass voltage Vpass4 are not particularly limited in the present disclosure, and may be selected according to actual situations.

At a second time T2, a programming voltage Vpgm is applied to the selected word line. Here, considering that the programming voltage Vpgm is larger, the selected word line may be boosted twice to reach the programming voltage Vpgm, where the selected word line is first boosted to the initial programming voltage Vpgm0 at the first time T1, and the selected word line is then boosted to the programming voltage Vpgm greater than the initial programming voltage Vpgm0 at the second time T2.

At a third time T3, a third pass voltage Vpass3 greater than the fourth pass voltage Vpass4 is applied to the second group of word lines (Vpass3=Vpass4+ΔV2 as illustrated in FIG. 9).

At a fourth time T4, a second pass voltage Vpass2 greater than the first pass voltage Vpass1 is applied to the first group of word lines (Vpass2=Vpass1+ΔV1 as illustrated in FIG. 9).

In some examples, the second pass voltage Vpass2 and the third pass voltage Vpass3 may be the same or different. The specific values of the second pass voltage Vpass2 and the third pass voltage Vpass3 are not particularly limited in the present disclosure, and may be selected according to actual situations.

At a fifth time T5, the selected word line starts to be discharged.

At a sixth time T6, the first and second group of word lines start to be discharged.

Here, the first pass voltage Vpass1 is applied to the first group of word lines from the first time T1 through the fourth time T4, and in this process, the voltage of the first group of word lines may be ramped up to the first pass voltage Vpass1 and remain stable. The start time of the first time period may be the first time T1, and the end time of the first time period may be the fourth time T4, and in this case, the first time period refers to a complete duration from the first time T1 through the fourth time T4. Of course, the first time period may also refer to at least some of the duration from the first time T1 through the fourth time T4.

Here, the second pass voltage Vpass2 is applied to the first group of word lines from the fourth time T4 to the sixth time T6, and in this process, the voltage of the first group of word lines may be ramped up to the second pass voltage Vpass2 and remain stable. The start time of the second time period may be the fourth time T4, and the end time of the second time period may be the sixth time T6, and in this case, the second time period refers to a complete duration from the fourth time T4 to the sixth time T6. Of course, the second time period may also refer to at least some of the duration from the fourth time T4 to the sixth time T6.

In some examples, the peripheral circuit 302 is further configured to: in the first programming operation, apply a fourth pass voltage Vpass4 less than the third pass voltage Vpass3 to the second group of word lines for a fourth time period prior to the third time period.

Here, the fourth pass voltage Vpass4 is applied to the second group of word lines from the first time T1 through the third time T3, and in this process, the voltage of the second group of word lines may be ramped up to the fourth pass voltage Vpass4 and remain stable. The start time of the fourth time period may be the first time T1, and the end time of the fourth time period may be the third time T3, and in this case, the fourth time period refers to a complete duration from the first time T1 through the third time T3. Of course, the fourth time period may also refer to at least some of the duration from the first time T1 through the third time T3.

Here, the third pass voltage Vpass3 is applied to the second group of word lines from the third time T3 to the sixth time T6, and in this process, the voltage of the second group of word lines may be ramped up to the third pass voltage Vpass3 and remain stable. The start time of the third time period may be the third time T3, and the end time of the third time period may be the sixth time T6, and in this case, the third time period refers to a complete duration from the third time T3 to the sixth time T6. Of course, the third time period may also refer to at least some of the duration from the third time T3 to the sixth time T6.

In an example of the present disclosure, the first time period is prior to the second time period, and there is no overlap between the first time period and the second time period; and the fourth time period is prior to the third time period, and there is no overlap between the fourth time period and the third time period. There is unoverlapped parts between the second time period and the third time period.

In some examples, the third pass voltage Vpass3 is greater than the first pass voltage Vpass1. Here, the third pass voltage Vpass3 refers to a target voltage for performing a second boosting process on the second group of word lines, and the first pass voltage Vpass1 refers to a target voltage for performing a first boosting process on the first group of word lines.

In some examples, the start time (e.g., fourth time T4) of the second time period is later than the start time (e.g., third time T3) of the third time period, that is, the start time when the second pass voltage Vpass2 is applied to the first group of word lines is later than the start time when the third pass voltage Vpass3 is applied to the second group of word lines. FIG. 10 takes the above case as an example for illustration.

In some other examples, the start time of the second time period is earlier than the start time of the third time period.

In some examples, a time difference between the start time of the second time period and the start time of the third time period is in a range of 1 through 6 microseconds, that is, a duration of a non-overlap portion between the second time period and the third time period (ΔT as shown in FIG. 10) is 1 through 6 microseconds.

In some examples, the peripheral circuit 302 is further configured to: in the first programming operation, apply a programming voltage Vpgm to the selected word line for the fifth time period; where the start time of the second time period and the start time of the third time period are later than the start time of the fifth time period, and the start time of the second time period and the start time of the third time period are earlier than the end time of the fifth time period. That is, both the start time when the second pass voltage Vpass2 is applied to the first group of word lines (e.g., the fourth time T4) and the start time when the third pass voltage Vpass3 is applied to the second group of word lines (e.g., the third time T3) are later than the start time when the programming voltage Vpgm is applied to the selected word line (e.g., the second time T2), and both the start time when the second pass voltage Vpass2 is applied to the first group of word lines and the start time when the third pass voltage Vpass3 is applied to the second group of word lines are earlier than the end time when the programming voltage Vpgm is applied to the selected word line (e.g., the fifth time T5). Here, considering that the second boosting is performed on the first group of word lines and the second group of word lines such that the voltages of the selected word line may be coupled up twice, thus the start time when the second boosting is performed on the first group of word lines and the second group of word lines needs to be within a fifth time period when the programming voltage is applied to the selected word line, that is, between the second time T2 and the fifth time T5.

Here, the start time of the fifth time period may be the second time T2 (or the first time T1), and the end time of the fifth time period may be the fifth time T5, and in this case, the fifth time period refers to a complete duration from the second time T2 (or the first time T1) through the fifth time T5. Of course, the fifth time period may also refer to at least some of the duration from the second time T2 (or the first time T1) through the fifth time T5. When the start time of the fifth time period is the second time T2, the selected word line is boosted twice to reach the programming voltage Vpgm; and when the start time of the fifth time period is the first time T1, the selected word line is boosted once to reach the programming voltage Vpgm.

Here, the distance between the first group of word lines and the selected word line and the distance between the third group of word lines and the selected word line are close, the distance between the second group of word lines and the selected word line and the distance between the fourth group of word lines and the selected word line are close, and the distance between the unselected word lines and the selected word line affects the degree of impact on the voltages of the unselected word lines, and therefore, the timing of the first group of word lines and the timing of the third group of word lines are controlled to be the same, and the timing of the second group of word lines and the timing of the fourth group of word lines are controlled to be the same.

In some examples, the peripheral circuit 302 is further configured to: in the first programming operation, apply a fifth pass voltage Vpass5 to the third group of word lines for a first time period; apply a sixth pass voltage Vpass6 (Vpass6=Vpass5+ΔV3 as illustrated in FIG. 9) greater than the fifth pass voltage Vpass5 to the third group of word lines for a second time period; apply a seventh pass voltage Vpass7 to the fourth group of word lines for a fourth time period; and apply an eighth pass voltage Vpass8 (Vpass8=Vpass7+ΔV4 as illustrated in FIG. 9) greater than the seventh pass voltage Vpass7 to the fourth group of word lines for a third time period.

In some examples, the first pass voltage Vpass1, the fourth pass voltage Vpass4, the fifth pass voltage Vpass5, and the seventh pass voltage Vpass7 may be the same or different. The specific values of the fifth pass voltage Vpass5 and the seventh pass voltage Vpass7 are not particularly limited in the present disclosure, and may be selected according to actual situations.

In some examples, the second pass voltage Vpass2, the third pass voltage Vpass3, the sixth pass voltage Vpass6, and the eighth pass voltage Vpass8 may be the same or different. The specific values of the sixth pass voltage Vpass6 and the eighth pass voltage Vpass8 are not particularly limited in the present disclosure, and may be selected according to actual situations.

FIG. 10 illustrates that the first group of word lines and the third group of word lines share the same voltage variation curve, which does not indicate that the first pass voltage Vpass1 and the fifth pass voltage Vpass5 are the same, and does not indicate that the second pass voltage Vpass2 and the sixth pass voltage Vpass6 are the same. Here, the same voltage variation curve is just used for simplifying the controlling of the timing of the first group of word lines and the timing of the third group of word lines to be the same. Similarly, the second group of word lines and the fourth group of word lines share the same voltage variation curve, which is just used for simplifying the controlling of the timing of the second group of word lines and the timing of the fourth group of word lines to be the same.

In this example, the first group of word lines, the second group of word lines, the third group of word lines, and the fourth group of word lines may all be boosted twice to reach the target pass voltage, where the timing of the first group of word lines and the timing of the third group of word lines may be controlled to be the same, and the timing of the second group of word lines and the timing of the fourth group of word lines may be controlled to be the same. The start time of the first boosting process of the first group of word lines (or the third group of word lines) and the start time of the first boosting process of the second group of word lines (or the fourth group of word lines) may be the same, and the start time of the second boosting process of the first group of word lines (or the third group of word lines) and the start time of the second boosting process of the second group of word lines (or the fourth group of word lines) needs to be staggered. In this way, in the second boosting process of the first group of word lines (or the third group of word lines), the voltages of the selected word line may be coupled up for the first time, and in the second boosting process of the second group of word lines (or the fourth group of word lines), the voltages of the selected word line may be coupled up for the second time, so as to increase the effective voltages of the selected word line, and improve the voltage difference between the near end of the selected word line and the far end of the selected word line.

Based on the above descriptions, the voltage difference between the near end of the selected word line and the far end of the selected word line under different situations may be compared and analyzed. In the first case, the first group of word lines are boosted twice to reach the target pass voltage, and the second group of word lines are boosted once to reach the target pass voltage, and the voltage difference between the near end of the selected word line and the far end of the selected word line at a certain time is the first voltage difference. In the second case, both the first group of word lines and the second group of word lines are boosted twice to reach the target pass voltage, and the start time of the second boosting process of the first group of word lines and the start time of the second boosting process of the second group of word lines are different (e.g., staggered), and the voltage difference between the near end of the selected word line and the far end of the selected word line at a certain time is the second voltage difference. In a third case, both the first group of word lines and the second group of word lines are boosted twice to reach the target pass voltage, and the start time of the second boosting process of the first group of word lines and the start time of the second boosting process of the second group of word lines are the same (e.g., not staggered), and the voltage difference between the near end of the selected word line and the far end of the selected word line at a certain time is the third voltage difference. The first voltage difference and the second voltage difference are substantially the same and greater than the second voltage difference. That is, after the start times of the second boosting process of the unselected word lines are staggered provided by the example of the present disclosure, the voltage difference between the near end of the selected word line and the far end of the selected word line may be improved.

It should be noted that, in the third case above, the start time of the second boosting process of the first group of word lines and the start time of the second boosting process of the second group of word lines are the same, and the voltage of the selected word line is coupled up once at the start time of the second boosting process of the first group of word lines and the start time of the second boosting process of the second group of word lines. In the second case above, the start time of the second boosting process of the first group of word lines and the start time of the second boosting process of the second group of word lines are different, for example, the start time of the second boosting process of the first group of word lines is later than the start time of the second boosting process of the second group of word lines, and the voltage of the selected word line is coupled up for the first time at the start time of the second boosting process of the first group of word lines; and the voltage of the selected word line is coupled up for the second time at the start time of the second boosting process of the second group of word lines, such that the effective voltage of the selected word line may be increased.

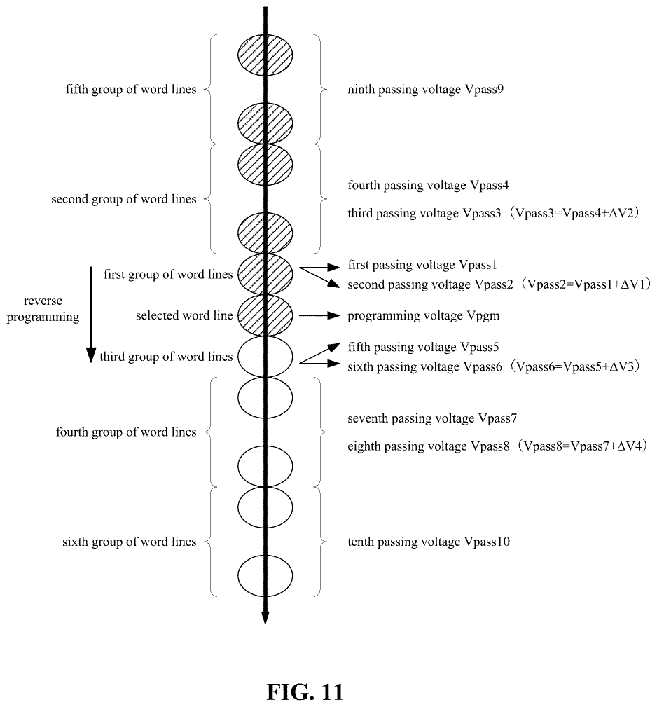

Referring to FIG. 11, FIG. 11 is a schematic diagram of performing programming operations on different word lines provided by some other examples of the present disclosure. In some examples, the unselected word lines further comprise: a fifth group of word lines and a sixth group of word lines, the second group of word lines is arranged between the first group of word lines and the fifth group of word lines, that is, the first group of word lines, the second group of word lines, and the fifth group of word lines are all arranged between the bit lines and the selected word line; and the fourth group of word lines is arranged between the third group of word lines and the sixth group of word lines, that is, the third group of word lines, the fourth group of word lines, and the sixth group of word lines are all arranged between the source line and the selected word line.

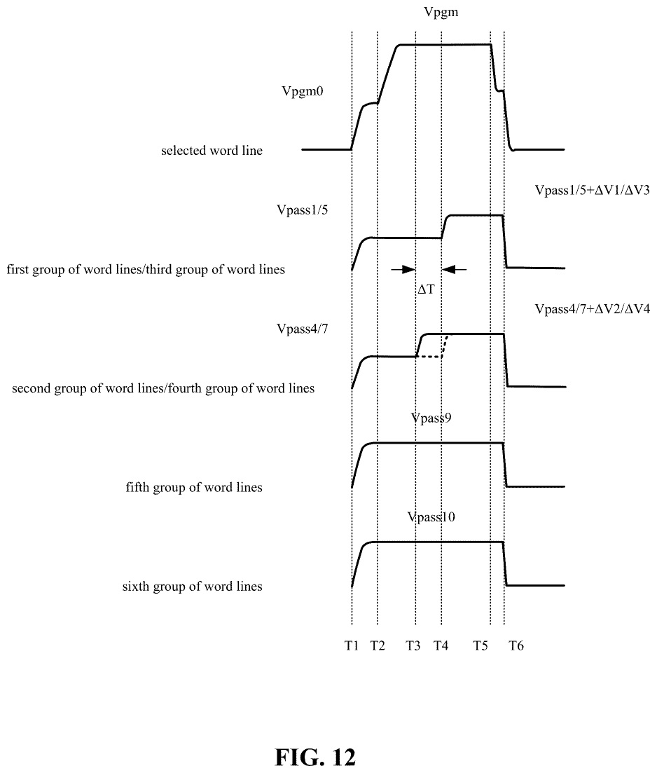

Referring to FIG. 12, FIG. 12 is a timing diagram of performing programming operations on different word lines provided by some other examples of the present disclosure. As shown in FIG. 4, FIG. 11, and FIG. 12, the peripheral circuit 302 is further configured to: in the first programming operation, apply a ninth pass voltage Vpass9 to the fifth group of word lines, and apply a tenth pass voltage Vpass10 to the sixth group of word lines for a sixth time period; where the sixth time period comprises a sum of the first time period and the second time period; or the sixth time period comprises a sum of the fourth time period and the third time period. Here, the timing of the fifth group of word lines and the timing of the sixth group of word lines are controlled to be the same. It should be noted that the process of applying the pass voltages to the first group of word lines, the second group of word lines, the third group of word lines, and the fourth group of word lines may be referred to the related text description of FIG. 9 and FIG. 10, and details are not described herein again.

The following will be described in detail with reference to FIG. 12. As shown in FIG. 12, in the process of performing the first programming operation, a ninth pass voltage Vpass9 is applied to the fifth group of word lines and a tenth pass voltage Vpass10 is applied to the sixth group of word lines at the first time T1.

In some examples, the ninth pass voltage Vpass9 and the tenth pass voltage Vpass10 may be the same or different. The specific values of the ninth pass voltage Vpass9 and the tenth pass voltage Vpass10 are not particularly limited in the present disclosure, and may be selected according to actual situations.

At a sixth time T6, the fifth group of word lines and the sixth group of word lines start to be discharged.

Here, from the first time T1 through the sixth time T6, the ninth pass voltage Vpass9 is applied to the fifth group of word lines and the tenth pass voltage Vpass10 is applied to the sixth group of word lines, and in this process, the voltage of the fifth group of word lines may be ramped up to the ninth pass voltage Vpass9 and remain stable, and the voltage of the sixth group of word lines may be ramped up to the tenth pass voltage Vpass10 and remain stable. The start time of the sixth time period may be the first time T1, and the end time of the sixth time period may be the sixth time T6, and in this case, the sixth time period may refer to a complete duration from the first time T1 through the sixth time T6. Of course, the sixth time period may also refer to at least some of the duration from the first time T1 through the sixth time T6.

In this example, both the fifth group of word lines and the sixth group of word lines may be boosted once to reach the target pass voltage, where the timing of the fifth group of word lines and the timing of the sixth group of word lines may be controlled to be the same. Here, compared with the distance between the first group of word lines and the selected word line, the distance between the second group of word lines and the selected word line, the distance between the third group of word lines and the selected word line, and the distance between the fourth group of word lines and the selected word line, the distance between the fifth group of word lines and the selected word line and the distance between the sixth group of word lines and the selected word line are larger, even if both the fifth group of word lines and the sixth group of word lines are boosted twice to reach the target pass voltage, the second boosting process of the fifth group of word lines and the second boosting process of the sixth group of word lines have limited impact on the selected word line. Therefore, both the fifth group of word lines and the sixth group of word lines may be boosted once to reach the target pass voltage.

In some examples, the peripheral circuit 302 is further configured to: in the first programming operation, at the end time of the fifth time period, for example, at the fifth time T5, the selected word line starts to be discharged; at the end time of the second time period, or at the end time of the third time period, or at the end time of the sixth time period, for example, at the sixth time T6, the unselected word lines start to be discharged. Here, since the programming voltage Vpgm is larger, the time when the selected word line starts to be discharged is earlier than the time when the unselected word lines start to be discharged, wherein the unselected word lines may comprise the first group of word lines, the second group of word lines, the third group of word lines, the fourth group of word lines, the fifth group of word lines, and the sixth group of word lines.

In some examples, the start time of the first time period, the start time of the fourth time period, and the start time of the sixth time period (for example, all of them are the first time T1) are the same, the end time of the second time period, the end time of the third time period, and the end time of the sixth time period (for example, all of them are the sixth time T6) are the same, and are later than the end time of the fifth time period (for example, the fifth time T5).

In the example of the present disclosure, the programming voltage applied to the selected word line and the target pass voltage applied to the unselected word lines may be controlled by using the voltage controller, and the time when the programming voltage is applied to the selected word line and the time when the target pass voltage is applied to the unselected word lines may be controlled by using the timing controller, and the start time of the second boosting process of the unselected word lines is staggered, such that the read margin of the memory device is improved.

It should be noted that, in the examples of the present disclosure, the unselected word lines comprising the first, second, third, fourth, fifth and sixth group of word lines are taken as an example for description. In practice, the unselected word lines may be divided into more groups, such that the control process of applying the target pass voltage to the unselected word lines may be finer, and even each unselected word line may be treated as a separate group, and the target pass voltage of each unselected word line and the start time when the target pass voltage is applied may be controlled. However, on the one hand, the more the grouping of the unselected word line, the more complex the control process of applying the target pass voltage to the unselected word lines, the more resources in the memory device are occupied; on the other hand, the more the grouping of the unselected word lines, the more time it takes to stagger the start time of the second boosting process of the unselected word lines in different groups, it results in longer time spent in the first programming operation. Therefore, it is needed to balance read margin and programming duration to select the number of groups of unselected word lines properly.

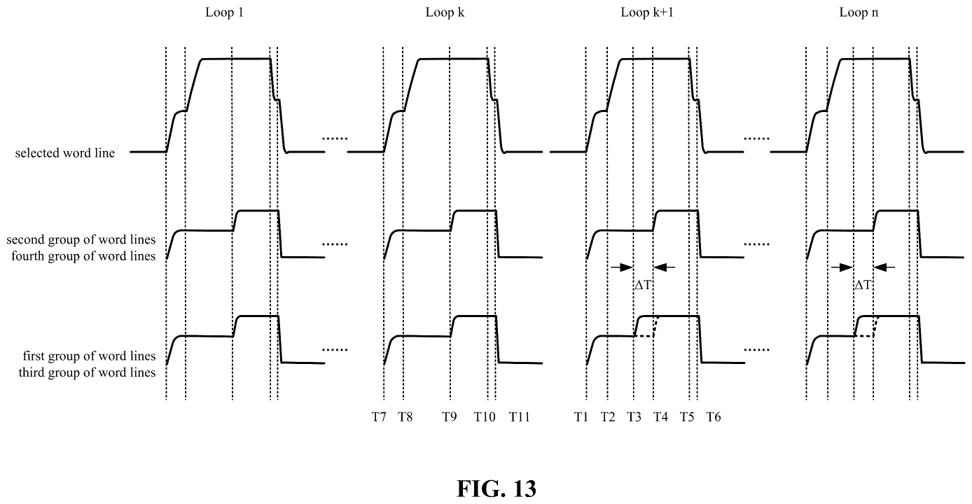

Referring to FIG. 13, FIG. 13 is a timing diagram of performing programming operations on different word lines provided by still other examples of the present disclosure. In some examples, the peripheral circuit 302 is further configured to: in a second programming operation prior to the first programming operation, apply a first pass voltage Vpass1 to the first group of word lines, and apply a fifth pass voltage Vpass5 to the third group of word lines for a seventh time period; apply a second pass voltage Vpass2 to the first group of word lines, and apply a sixth pass voltage Vpass6 to the third group of word lines for an eighth time period after the seventh time period; apply a fourth pass voltage Vpass4 to the second group of word lines, and apply a seventh pass voltage Vpass7 to the fourth group of word lines for a ninth time period; and apply a third pass voltage Vpass3 to the second group of word lines, and apply an eighth pass voltage Vpass8 to the fourth group of word lines for a tenth time period after the ninth time period; where the start time of the seventh time period is the same as the start time of the ninth time period, the start time of the eighth time period is the same as the start time of the tenth time period.

Taking the programming loop k illustrated in FIG. 13 as an example for description, in the second programming operation, at a seventh time T7, an initial programming voltage Vpgm0 is applied to the selected word line, a first pass voltage Vpass1 is applied to the first group of word lines, a fourth pass voltage Vpass4 is applied to the second group of word lines, a fifth pass voltage Vpass5 is applied to the third group of word lines, and a seventh pass voltage Vpass7 is applied to the fourth group of word lines.

At an eighth time T8, a programming voltage Vpgm is applied to the selected word line.

At a ninth time T9, a second pass voltage Vpass2 is applied to the first group of word lines, a third pass voltage Vpass3 is applied to the second group of word lines, a sixth pass voltage Vpass6 is applied to the third group of word lines, and an eighth pass voltage Vpass8 is applied to the fourth group of word lines.

At a tenth time T10, the selected word line starts to be discharged.

At an eleventh time T11, the first, second, third, and fourth group of word lines start to be discharged.

Here, from the seventh time T7 through the ninth time T9, the first boosting process is performed on the first group of word lines and the third group of word lines, and the first boosting process is performed on the second group of word lines and the fourth group of word lines. Both the start time of the seventh time period and the start time of the ninth time period may be the seventh time T7, and both the end time of the seventh time period and the end time of the ninth time period may be the ninth time T9, and in this case, the seventh time period and the ninth time period refer to a complete duration from the seventh time T7 through the ninth time T9. Of course, the seventh time period and the ninth time period may also refer to at least some of the duration from the seventh time T7 through the ninth time T9.

Here, from the ninth time T9 through the eleventh time T11, the second boosting process is performed on the first group of word lines and the third group of word lines, and the second boosting process is performed on the second group of word lines and the fourth group of word lines. Both the start time of the eighth time period and the start time of the tenth time period may be the ninth time T9, and both the end time of the eighth time period and the end time of the tenth time period may be the eleventh time T11, and in this case, the eighth time period and the tenth time period refer to a complete duration from the ninth time T9 through the eleventh time T11. Of course, the eighth time period and the tenth time period may also refer to at least some of the duration from the ninth time T9 through the eleventh time T11.

In the second programming operation of this example, the start time of the seventh time period is the same as the start time of the ninth time period, and the end time of the seventh time period is the same as the end time of the ninth time period, that is, the seventh time period and the ninth time period are completely overlapped. The start time of the eighth time period is the same as the start time of the tenth time period, and the end time of the eighth time period is the same as the end time of the tenth time period, that is, the eighth time period and the tenth time period are completely overlapped. That is, in the second programming operation, the start times of the second boosting process of the first group of word lines, the second group of word lines, the third group of word lines, and the fourth group of word lines are the same, and the voltage of the selected word line is coupled up once.

In this example, programming loop 1 through programming loop k are all second programming operations, and programming loop k+1 through programming loop n are all first programming operations; where k is greater than or equal to 1, k+1 is less than or equal to n, and both k and n are integers. Here, considering that the start time of the second boosting process of the first group of word lines (or the third group of word lines) and the start time of the second boosting process of the second group of word lines (or the fourth group of word lines) are staggered, it results that the time for applying the target pass voltage to a part of the unselected word lines (that is, a part of unselected word lines with an earlier start time of the second boosting process) is prolonged, thereby resulting in an increase in the Vpass disturb. Further, in order to balance the Vpass disturb and the read margin of the memory device, the start time of the second boosting process of unselected word lines may be kept the same in programming loop 1 through programming loop k to reduce the Vpass disturb. After the k programming loops, the start times of the second boosting process of unselected word lines are staggered in programming loop k+1 through programming loop n, such that the read margin of the memory device is increased.

Here, the specific value of k is not particularly limited in the present disclosure. The k value may be obtained by test verification, for example, a series of k values are set, a threshold voltage distribution diagram is obtained after the programming loops are executed, and the appropriate k value is determined by balancing the Vpass disturb and the read margin of the memory device.

Referring back to FIG. 1, an example of the present disclosure provides a memory system, the memory system 102 comprises: a memory device 104 in the above technical solution; and a controller 106 coupled to the memory device 104 and configured to control the memory device 104.

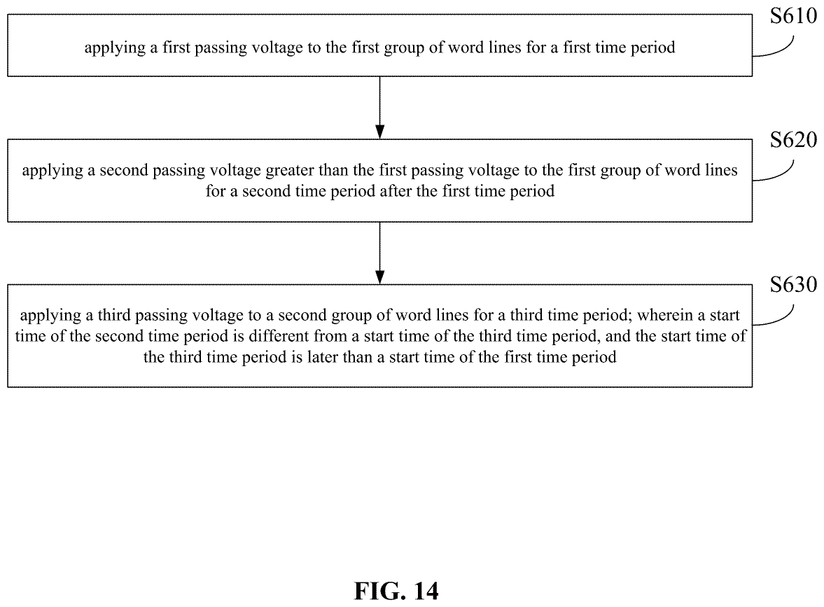

Referring to FIG. 14, FIG. 14 is a schematic flowchart of an operating method of a memory device provided by an example of the present disclosure. As shown in FIG. 14, an example of the present disclosure provides an operating method of a memory device, a plurality of word lines comprise a selected word line and unselected word lines, and the unselected word line comprise at least a first group of word lines and a second group of word lines; in a first programming operation, the operating method comprises:

Operation SS610: applying a first pass voltage to the first group of word lines for a first time period;

Operation SS620: applying a second pass voltage greater than the first pass voltage to the first group of word lines for a second time period after the first time period;

Operation SS630: applying a third pass voltage to the second group of word lines for a third time period; wherein a start time of the second time period is different from a start time of the third time period, and the start time of the third time period is later than a start time of the first time period.

In some examples, the third pass voltage is greater than the first pass voltage.

In some examples, the first programming operation further comprises: applying a fourth pass voltage less than the third pass voltage to the second group of word lines for a fourth time period prior to the third time period.

In some examples, the start time of the second time period is earlier than the start time of the third time period; or the start time of the second time period is later than the start time of the third time period.

In some examples, a time difference between the start time of the second time period and the start time of the third time period is in a range of 1 through 6 microseconds.

In some examples, the first programming operation further comprises: applying a programming voltage to the selected word line for a fifth time period; wherein the start time of the second time period and the start time of the third time period are later than a start time of the fifth time period, and the start time of the second time period and the start time of the third time period are earlier than an end time of the fifth time period.

In some examples, the selected word line is arranged between the first group of word lines and the second group of word lines.

In some examples, the first group of word lines are arranged between the selected word line and the second group of word lines.

In some examples, the memory device further comprises: a plurality of bit lines coupled to a memory cell array; a source line coupled to the memory cell array; the unselected word lines further comprise: a third group of word lines and a fourth group of word lines, the third group of word lines are arranged between the selected word line and the fourth group of word lines; wherein both the first group of word lines and the second group of word lines are arranged between the selected word line and the bit lines, and both the third group of word lines and the fourth group of word lines are arranged between the selected word line and the source line; or both the first group of word lines and the second group of word lines are arranged between the selected word line and the source line, and both the third group of word lines and the fourth group of word lines are arranged between the selected word line and the bit lines.

In some examples, the first programming operation further comprises: applying a fifth pass voltage to the third group of word lines for the first time period; applying a sixth pass voltage greater than the fifth pass voltage to the third group of word lines for the second time period; applying a seventh pass voltage to the fourth group of word lines for the fourth time period; and applying an eighth pass voltage greater than the seventh pass voltage to the fourth group of word lines for the third time period.

In some examples, the unselected word lines further comprise: a fifth group of word lines and a sixth group of word lines, the second group of word lines are arranged between the first group of word lines and the fifth group of word lines, and the fourth group of word lines are arranged between the third group of word lines and the sixth group of word lines; the first programming operation further comprises: applying a ninth pass voltage to the fifth group of word lines, and applying a tenth pass voltage to the sixth group of word lines for a sixth time period; wherein the sixth time period comprises a sum of the first time period and the second time period; or the sixth time period comprises a sum of the fourth time period and the third time period.

In some examples, the start time of the first time period, the start time of the fourth time period, and a start time of the sixth time period are the same, an end time of the second time period, an end time of the third time period, and an end time of the sixth time period are the same, and are later than an end time of the fifth time period.

In some examples, the first programming operation further comprises: starting to be discharged the selected word line at the end time of the fifth time period; and starting to be discharged the unselected word lines at the end time of the second time period.

In some examples, prior to the first programming operation, the operation method further comprises a second programming operation comprising: applying the first pass voltage to the first group of word lines, and applying the fifth pass voltage to the third group of word lines for a seventh time period; applying the second pass voltage to the first group of word lines, and applying the sixth pass voltage to the third group of word lines for an eighth time period after the seventh time period; applying the fourth pass voltage to the second group of word lines, and applying the seventh pass voltage to the fourth group of word lines for a ninth time period; and applying the third pass voltage to the second group of word lines, and applying the eighth pass voltage to the fourth group of word lines for a tenth time period after the ninth time period; wherein a start time of the seventh time period and a start time of the ninth time period are the same, and a start time of the eighth time period and a start time of the tenth time period are the same.

In some examples, when the first programming operation is in forward programming, memory cells coupled to a group of word lines arranged between the selected word line and the source line are in a programmed state, and memory cells coupled to a group of word lines arranged between the selected word line and the bit lines are in an unprogrammed state; or when the first programming operation is in reverse programming, memory cells coupled to a group of word lines arranged between the selected word line and the source line are in an unprogrammed state, and memory cells coupled to a group of word lines arranged between the selected word line and the bit lines are in a programmed state.

The examples of the present disclosure provide a memory device, an operation method thereof, and a memory system. The memory device comprises: a memory cell array; a plurality of word lines coupled to the memory cell array, wherein the plurality of word lines comprise a selected word line and unselected word lines, and the unselected word lines comprise at least a first group of word lines and a second group of word lines; and a peripheral circuit coupled to the memory cell array and the word lines, wherein the peripheral circuit is configured to: in a first programming operation, apply a first pass voltage to the first group of word lines for a first time period; apply a second pass voltage greater than the first pass voltage to the first group of word lines for a second time period after the first time period; and apply a third pass voltage to the second group of word lines for a third time period; wherein a start time of the second time period is different from a start time of the third time period, and the start time of the third time period is later than a start time of the first time period. In the examples of the present disclosure, in a process of boosting the second group of word lines to the third pass voltage and boosting the first group of word lines to the second pass voltage, the voltages of the selected word line may be coupled up twice to increase the effective voltages of the selected word line and improve the voltage difference between the near end of the selected word line and the far end of the selected word line, such that the read margin is increased, and in turn, the reliability of the memory device is improved.

In some examples, the third pass voltage is greater than the first pass voltage.

In some examples, the peripheral circuit is further configured to: in the first programming operation, apply a fourth pass voltage less than the third pass voltage to the second group of word lines for a fourth time period prior to the third time period.

In some examples, the start time of the second time period is earlier than the start time of the third time period; or the start time of the second time period is later than the start time of the third time period.

In some examples, a time difference between the start time of the second time period and the start time of the third time period is in a range of 1 through 6 microseconds.

In some examples, the peripheral circuit is further configured to: in the first programming operation, apply a programming voltage to the selected word line for a fifth time period; wherein the start time of the second time period and the start time of the third time period are later than a start time of the fifth time period, and the start time of the second time period and the start time of the third time period are earlier than an end time of the fifth time period.

In some examples, the selected word line is arranged between the first group of word lines and the second group of word lines.

In some examples, the first group of word lines are arranged between the selected word line and the second group of word lines.

In some examples, the memory device further comprises: a plurality of bit lines coupled to the memory cell array; a source line coupled to the memory cell array; the unselected word lines further comprise: a third group of word lines and a fourth group of word lines, the third group of word lines are arranged between the selected word line and the fourth group of word lines; wherein both the first group of word lines and the second group of word lines are arranged between the selected word line and the bit lines, and both the third group of word lines and the fourth group of word lines are arranged between the selected word line and the source line; or both the first group of word lines and the second group of word lines are arranged between the selected word line and the source line, and both the third group of word lines and the fourth group of word lines are arranged between the selected word line and the bit lines.

In some examples, the peripheral circuit is further configured to: in the first programming operation, apply a fifth pass voltage to the third group of word lines for the first time period; apply a sixth pass voltage greater than the fifth pass voltage to the third group of word lines for the second time period; apply a seventh pass voltage to the fourth group of word lines for the fourth time period; and apply an eighth pass voltage greater than the seventh pass voltage to the fourth group of word lines for the third time period.

In some examples, the unselected word lines further comprise: a fifth group of word lines and a sixth group of word lines, the second group of word lines are arranged between the first group of word lines and the fifth group of word lines, and the fourth group of word lines are arranged between the third group of word lines and the sixth group of word lines; the peripheral circuit is further configured to: in the first programming operation, apply a ninth pass voltage to the fifth group of word lines, and apply a tenth pass voltage to the sixth group of word lines for a sixth time period; wherein the sixth time period comprises a sum of the first time period and the second time period; or the sixth time period comprises a sum of the fourth time period and the third time period.

In some examples, the start time of the first time period, the start time of the fourth time period, and a start time of the sixth time period are the same, an end time of the second time period, an end time of the third time period, and an end time of the sixth time period are the same, and are later than an end time of the fifth time period.

In some examples, the peripheral circuit is further configured to: in the first programming operation, start to discharge the selected word line at the end time of the fifth time period; and start to discharge the unselected word lines at the end time of the second time period.

In some examples, the peripheral circuit is configured to: in a second programming operation prior to the first programming operation, apply the first pass voltage to the first group of word lines, and apply the fifth pass voltage to the third group of word lines for a seventh time period; apply the second pass voltage to the first group of word lines, and apply the sixth pass voltage to the third group of word lines for an eighth time period after the seventh time period; apply the fourth pass voltage to the second group of word lines, and apply the seventh pass voltage to the fourth group of word lines for a ninth time period; and apply the third pass voltage to the second group of word lines, and apply the eighth pass voltage to the fourth group of word lines for a tenth time period after the ninth time period; wherein a start time of the seventh time period and a start time of the ninth time period are the same, and a start time of the eighth time period and a start time of the tenth time period are the same.

In some examples, when the first programming operation is in forward programming, memory cells coupled to a group of word lines arranged between the selected word line and the source line are in a programmed state, and memory cells coupled to a group of word lines arranged between the selected word line and the bit lines are in an unprogrammed state; or when the first programming operation is in reverse programming, memory cells coupled to a group of word lines arranged between the selected word line and the source line are in an unprogrammed state, and memory cells coupled to a group of word lines arranged between the selected word line and the bit lines are in a programmed state.

In some examples, the number of word lines comprised in the first group of word lines ranges from 1 through 5, and the number of word lines comprised in the third group of word lines ranges from 1 through 5.

It is to be understood that reference throughout the description to “one example” or “an example” means that a particular feature, structure or characteristic related to the example is included in at least one example of the present disclosure. Thus, the “in one example” or “in an example” appeared in various places throughout the description are not necessarily referring to the same example. Furthermore, these particular features, structures or characteristics may be combined into one or more examples in any appropriate way. It is to be understood that in various examples of the present disclosure, sequence numbers of the processes described above do not mean the order of execution, and the order of execution of each process is to be determined by its function and internal logic, and should not constitute any limitation to executing process of examples of the present disclosure. The serial numbers of examples of the present disclosure described above are just for the purpose of description, and do not represent the advantages and disadvantages of the examples.

The above description is just some examples of the present disclosure, and is not intended to limit the scope of the present disclosure, and under the inventive concept, any equivalent structural transformation made by using the present disclosure and the accompanying drawings, or direct/indirect application to other related arts are comprised within the scope of the present disclosure.

What is claimed is:

1. A memory device, comprising:
a memory cell array;
word lines coupled to the memory cell array, wherein the word lines comprise a selected word line and unselected word lines, and the unselected word lines comprise at least a first group of word lines and a second group of word lines; and
a peripheral circuit coupled to the memory cell array and the word lines, wherein the peripheral circuit is configured to: in a first programming operation,
during a first time period, apply a first pass voltage to the first group of word lines;
during a second time period after the first time period, apply a second pass voltage greater than the first pass voltage to the first group of word lines; and
during a third time period, apply a third pass voltage to the second group of word lines;
wherein a start time of the second time period is different from a start time of the third time period, and the start time of the third time period is later than a start time of the first time period.

2. The memory device of claim 1, wherein the third pass voltage is greater than the first pass voltage.

3. The memory device of claim 1, wherein the peripheral circuit is further configured to: in the first programming operation,
during a fourth time period prior to the third time period, apply a fourth pass voltage less than the third pass voltage to the second group of word lines;
wherein:
the start time of the second time period is earlier than the start time of the third time period; or
the start time of the second time period is later than the start time of the third time period.

4. The memory device of claim 3, wherein a time difference between the start time of the second time period and the start time of the third time period is in a range of 1 through 6 microseconds.

5. The memory device of claim 3, wherein the peripheral circuit is further configured to: in the first programming operation,
during a fifth time period, apply a programming voltage to the selected word line;
wherein the start time of the second time period and the start time of the third time period are later than a start time of the fifth time period, and the start time of the second time period and the start time of the third time period are earlier than an end time of the fifth time period.

6. The memory device of claim 5, wherein at least one memory cell coupled with the selected word line is arranged between memory cells coupled with the first group of word lines and memory cells coupled with the second group of word lines.

7. The memory device of claim 5, wherein at least one memory cell coupled with the first group of word lines are arranged between memory cells coupled with the selected word line and memory cells coupled with the second group of word lines.

8. The memory device of claim 7, wherein the memory device further comprises:
bit lines coupled to the memory cell array; and
a source line coupled to the memory cell array;
wherein the unselected word lines further comprise: a third group of word lines and a fourth group of word lines, wherein at least one memory cell coupled with the third group of word lines are arranged between memory cells coupled with the selected word line and memory cells coupled with the fourth group of word lines;
wherein:
both memory cells coupled with the first group of word lines and memory cells coupled with the second group of word lines are arranged between memory cells coupled with the selected word line and the bit lines, and both memory cells coupled with the third group of word lines and the memory cells coupled with the fourth group of word lines are arranged between memory cells coupled with the selected word line and the source line; or
both the memory cells coupled with the first group of word lines and the memory cells coupled with the second group of word lines are arranged between the memory cells coupled with the selected word line and the source line, and both the memory cells coupled with the third group of word lines and the memory cells coupled with the fourth group of word lines are arranged between the memory cells coupled with the selected word line and the bit lines.

9. The memory device of claim 8, wherein the peripheral circuit is further configured to: in the first programming operation,
during the first time period, apply a fifth pass voltage to the third group of word lines;
during the second time period, apply a sixth pass voltage greater than the fifth pass voltage to the third group of word lines;
during the fourth time period, apply a seventh pass voltage to the fourth group of word lines; and
during the third time period, apply an eighth pass voltage greater than the seventh pass voltage to the fourth group of word lines.

10. The memory device of claim 9, wherein the unselected word lines further comprise:
a fifth group of word lines and a sixth group of word lines, wherein memory cells coupled with the second group of word lines are arranged between the memory cells coupled with the first group of word lines and memory cells coupled with the fifth group of word lines, and the memory cells coupled with the fourth group of word lines are arranged between the memory cells coupled with the third group of word lines and memory cells coupled with the sixth group of word lines;
the peripheral circuit is further configured to: in the first programming operation,
during a sixth time period, apply a ninth pass voltage to the fifth group of word lines, and apply a tenth pass voltage to the sixth group of word lines;
wherein:
the sixth time period comprises a sum of the first time period and the second time period; or
the sixth time period comprises a sum of the fourth time period and the third time period.

11. The memory device of claim 10, wherein the start time of the first time period, the start time of the fourth time period, and a start time of the sixth time period are the same, an end time of the second time period, an end time of the third time period, and an end time of the sixth time period are the same, and are later than the end time of the fifth time period; and
the peripheral circuit is further configured to: in the first programming operation,
start to discharge the selected word line at the end time of the fifth time period; and
start to discharge the unselected word lines at the end time of the second time period.

12. The memory device of claim 9, wherein the peripheral circuit is configured to: in a second programming operation prior to the first programming operation,
during a seventh time period, apply the first pass voltage to the first group of word lines, and apply the fifth pass voltage to the third group of word lines;
during an eighth time period after the seventh time period, apply the second pass voltage to the first group of word lines, and apply the sixth pass voltage to the third group of word lines;
during a ninth time period, apply the fourth pass voltage to the second group of word lines, and apply the seventh pass voltage to the fourth group of word lines; and
during a tenth time period after the ninth time period, apply the third pass voltage to the second group of word lines, and apply the eighth pass voltage to the fourth group of word lines;
wherein a start time of the seventh time period and a start time of the ninth time period are the same, and a start time of the eighth time period and a start time of the tenth time period are the same.

13. A memory system, comprising:
a memory device, comprising:
a memory cell array;
word lines coupled to the memory cell array, wherein the word lines comprise a selected word line and unselected word lines, and the unselected word lines comprise at least a first group of word lines and a second group of word lines; and
a peripheral circuit coupled to the memory cell array and the word lines, wherein the peripheral circuit is configured to: in a first programming operation,
during a first time period, apply a first pass voltage to the first group of word lines;
during a second time period after the first time period, apply a second pass voltage greater than the first pass voltage to the first group of word lines; and
during a third time period, apply a third pass voltage to the second group of word lines;
wherein a start time of the second time period is different from a start time of the third time period, and the start time of the third time period is later than a start time of the first time period;
a controller coupled to the memory device and configured to control the memory device.

14. An operating method of a memory device, comprising: in a first programming operation,
during a first time period, applying a first pass voltage to a first group of word lines of unselected word lines;
during a second time period after the first time period, applying a second pass voltage greater than the first pass voltage to the first group of word lines; and
during a third time period, applying a third pass voltage to a second group of word lines of the unselected word lines;
wherein a start time of the second time period is different from a start time of the third time period, and the start time of the third time period is later than a start time of the first time period.

15. The operating method of claim 14, wherein the third pass voltage is greater than the first pass voltage.

16. The operating method of claim 14, further comprising: in the first programming operation,
during a fourth time period prior to the third time period, applying a fourth pass voltage less than the third pass voltage to the second group of word lines;
wherein:
the start time of the second time period is earlier than the start time of the third time period; or
the start time of the second time period is later than the start time of the third time period.

17. The operating method of claim 16, further comprising: in the first programming operation,
during a fifth time period, applying a programming voltage to a selected word line;
wherein the start time of the second time period and the start time of the third time period are later than a start time of the fifth time period, and the start time of the second time period and the start time of the third time period are earlier than an end time of the fifth time period.

18. The operating method of claim 17, wherein at least one memory cell coupled with the first group of word lines are arranged between memory cells coupled with the selected word line and memory cells coupled with the second group of word lines.

19. The operating method of claim 18, further comprising: in the first programming operation,
during the first time period, applying a fifth pass voltage to a third group of word lines of the unselected word lines;
during the second time period, applying a sixth pass voltage greater than the fifth pass voltage to the third group of word lines;
during the fourth time period, applying a seventh pass voltage to a fourth group of word lines of the unselected word lines; and
during the third time period, applying an eighth pass voltage greater than the seventh pass voltage to the fourth group of word lines.

20. The operating method of claim 19, the first programming operation further comprising:
during a sixth time period, applying a ninth pass voltage to a fifth group of word lines of the unselected word lines; and
during the sixth time period, applying a tenth pass voltage to a sixth group of word lines of the unselected word lines;
starting to discharge the selected word line at the end time of the fifth time period; and
starting to discharge the unselected word lines at the end time of the second time period;
wherein memory cells coupled with the second group of word lines are arranged between memory cells coupled with the first group of word lines and memory cells coupled with the fifth group of word lines, memory cells coupled with the fourth group of word lines are arranged between memory cells coupled with the third group of word lines and memory cells coupled with the sixth group of word lines, wherein:
the sixth time period comprises a sum of the first time period and the second time period; or
the sixth time period comprises a sum of the fourth time period and the third time period.
